(19) United States
(12) Patent Application Publication
(10) Pub. No.: US 2016/0211101 A1
(43) Pub. Date: Jul. 21, 2016

(54) PORTABLE CIRCUIT-BREAKER TRIPPER APPARATUS AND METHOD OF USING SAME

(71) Applicants: RAYMOND ANTHONY JOAO, YONKERS, NY (US); GREGORY THOMAS JOAO, YONKERS, NY (US); STEPHEN RAYMOND ANDERSON, YORKTOWN HEIGHTS, NY (US)

(72) Inventors: RAYMOND ANTHONY JOAO, YONKERS, NY (US); GREGORY THOMAS JOAO, YONKERS, NY (US); STEPHEN RAYMOND ANDERSON, YORKTOWN HEIGHTS, NY (US)

(21) Appl. No.: 14/988,414

(22) Filed: Jan. 5, 2016

Related U.S. Application Data
(60) Provisional application No. 62/106,101, filed on Jan. 21, 2015.

(51) Int. Cl. H01H 71/12; H01R 25/00; H01H 71/02; H05K 7/20; H01H 89/00; H01H 71/04

(52) U.S. Cl. CPC H01H 71/122; H01H 89/00; H01H 71/04; H01H 71/02; H05K 7/2039; H01R 25/006; H01H 2219/037

(57) ABSTRACT

An apparatus, including an electrical plug or a plurality of external electrical connectors; a first circuit, wherein the first circuit is an open circuit or an essentially open circuit; a second circuit, wherein the second circuit includes an indicator for indicating an electrical current flow in the second circuit; a third circuit, wherein the third circuit is designed to open a fuse or to trip a circuit breaker; and an electrical switch. The electrical switch is electrically connected to the electrical plug or to the plurality of external electrical connectors, wherein the electrical switch is capable of connecting the electrical plug or the plurality of external electrical connectors to the first circuit, to the second circuit, or to the third circuit.

### RELATED APPLICATIONS

This application claims the benefit of the priority of U.S. Provisional Patent Application Ser. No. 62/106,101, filed Jan. 21, 2015, and entitled “PORTABLE CIRCUIT-BREAKER TRIPPER APPARATUS AND METHOD OF USING SAME”, the subject matter and teachings of which are hereby incorporated by reference herein in their entirety.

### FIELD OF THE INVENTION

The present invention pertains to a portable circuit-breaker tripper apparatus and method of using same and, in particular, the present invention pertains to a portable circuit-breaker tripper apparatus and method of using same which can be used to safely open or “trip” a circuit associated with a circuit breaker or an electrical fuse.

### BACKGROUND OF THE INVENTION

Fuses and circuit-breakers, or other circuit opening or circuit breaking devices, are known in the prior art as being a useful safety device which protects circuits from damage and which protects people and property from harm, damage, or destruction. Further, these fuses or circuit-breakers allow a user, such as an electrician or a homeowner to deactivate or disconnect circuits from a power source so that the circuit can be worked on without the hazard of electrocution or other risk of damaging property. However, the fuse box or circuit-breaker box which typically houses many respective fuses or circuit breakers may not always be properly documented and/or may require trial-and-error on the part of a user, electrician, or homeowner to remove fuses or to trip circuit breakers, generally one at a time, and then to return to the, possibly remote location of the circuit components of interest, and to test to see if the removed fuse or the tripped circuit breaker was the ‘correct’ one for shutting off power to the circuit of interest. Often, this requires multiple trips back and forth to and from the fuse box or the circuit-breaker box. Additionally, this trial-and-error approach and process of the user, electrician, or homeowner can result in the shutting off or other, and unintended, circuits that would not have been otherwise been effected had the user, electrician, or homeowner known which fuse to remove or which circuit breaker to trip.

### SUMMARY OF THE INVENTION

The present invention pertains to a portable circuit-breaker tripper apparatus and method of using same and, in particular, the present invention pertains to a portable circuit-breaker tripper apparatus and method of using same which can be used to safely open or “trip” a circuit associated with a circuit breaker or an electrical fuse, which overcomes the shortfalls of the prior art and, therefore, the present invention provides an apparatus, and a method for using same, which is a useful tool for reliably and safely blowing a fuse or tripping a circuit breaker, while leaving other circuits unaffected.

The apparatus of the present invention can be equipped with an electrical plug which allows the apparatus of the present invention to interface with, or to be plugged into, an external circuit, or an electrical outlet, which can be a residential or other electrical outlet which can be associated with, and protected by, a circuit breaker or fuse.

Connected electrically to the electrical plug can be any appropriate electrical device or electrical load, or any electrical devices or electrical loads. An meter or a rectifying circuit, or any combination of same can also be electrically connected to and/or with the electrical plug. The electrical load or electrical loads may be connected to the electrical plug in either a series or parallel connection.

The apparatus can be equipped with a switching component or switch which can be connected in either a series or parallel connection with either the electrical plug and/or the electrical load.

The switching component or switch can be connected to an off load, a test load and/or a trip load. The position of the switching component or switch, or the position of the selecting component of same, can be used to electrically connect any of the off load, the test load and/or the trip load to or with the electrical load and/or the electrical plug.

The switching component or switch can be actuated by a selecting component which can, for example, be a mechanical dial or any other appropriate mechanical switch, button, touch screen, or similar device. In this manner, a user of the apparatus of the present invention can use the selecting component, dial, or switch to select which of the off load, the test load and/or the trip load is electrically connected to either the electrical plug and/or to the electrical load.

The off load can be an open circuit, or can be effected by any other device or configuration which would present a high and/or effectively infinite resistance to the rest of the apparatus of the present invention. In this regard, the off load represents a situation where the apparatus will not trip the circuit breaker or blow the fuse associated with circuit associated with that respective electrical outlet.

Ideally, no current, or a small leakage current, can flow through the apparatus when the switching component or switch is positioned such that the off load is electrically connected with either the electrical plug and/or the electrical load.

The test load can consist of a resistive component and/or a light emitting diode (LED), or any combination of same. The resistive component can be any device which serves to limit the amount of current, if available, flowing into the LED. The LED can be a light emitting diode, an organic light emitting diode, a buzzer, a speaker, and/or an alarm, and/or can be any other suitable device which is capable of indicating and/or producing a stimulus of light, sound, or any other indication.

When the switching component or switch is positioned such that the test load can be electrically connected with either the electrical plug and/or the electrical load, sufficient current can flow through the test load such that the LED produces a stimulus which can indicate to the user of the apparatus of the present invention that the external circuit which is connected to the apparatus is providing power or current to the apparatus.

The trip load can be a “short circuit” or minimal resistance load, or any other device or configuration which would present a low and/or effectively zero resistance, or a resistance which would result in the tripping of the circuit breaker or the blowing of a fuse associated with the circuit, which is associated with the electrical outlet, to the rest of the apparatus of the present invention.

A high current can flow through the apparatus when the switching component is positioned such that the trip load is electrically connected with either the electrical plug and/or the electrical load. Such a high current can trip the circuit breaker, and/or can destroy the fuse, of, for, or associated with, the external circuit associated with the electrical outlet from the location from which the apparatus is being operated.

A heat sink can be thermally coupled to the trip load, such that the high current that can flow through the trip load does not destroy the trip load or any equipment or wiring associated with the electrical outlet or the circuit, and also allow for the apparatus of the present invention to be reusable. The heat sink can be composed of, or manufactured from, with, or using, any suitable material so that it can prevent any device or component it is thermally coupled to from thermal damage, especially thermal damage due to high current. The heat sink can also be coupled to any other component and/or device of the apparatus of the present invention.

The switch, dial, and/or the switching device, can include, or be labeled with, any suitable markings or text in order to provide a user of the apparatus with information regarding, or a representation of, which of the off load, the test load, and/or the trip load, is currently selected by, or which can be selected by, the switch, dial, and/or the switching device. As and for an example, the switch, dial, or switching device, may read “OFF,” “TEST,” and “TRIP,” corresponding to the respective electrical connections of the off load, the test load and/or the trip load.

The use and operation of the apparatus of the present invention can be described as follows. With the switch, dial, and/or the switching device, being placed in the “OFF” position, the user can connect the electrical plug with the outlet of the external circuit. The user can then switch the operation or position of the switch, the dial, and/or the switching component, of the apparatus to the “TEST” position, and can use the output or lack of an output of the LED to determine if the external circuit is “live.” If the user desires to “trip” the circuit breaker or “blow” the fuse of the external circuit, without having or needing to be present at the location of the fuse or the circuit breaker, the user can simply switch the position of the switch, the dial, and/or the switching component, of the apparatus 100 to the “TRIP” position, effectively shorting the external circuit and tripping the circuit breaker and/or destroying the fuse. The user can then switch the position of switch, dial, and/or the switching component, of the apparatus 100 back to the “TEST” position in order to verify that the external circuit has been disabled.

The electrical load can contain a set of lead wires, alligator clips, or other connective components. In this manner, the apparatus of the present invention can also be interfaced with circuits that do not have an associated wall outlet or electrical outlet, or for which an associated wall outlet or electrical outlet is or may be unknown to the user. As and for an example, connecting the lead wires of the electrical load to the terminals of a light bulb socket can allow the operation of the apparatus to be used to disable the circuit associated with the light bulb socket and without the user needing to identify other components, such as a wall outlet or an electrical outlet, which are or may be on the same circuit as the light bulb socket. Similarly, the apparatus or device can be used to disable the circuit associated with a dimmer switch or any other switches or circuit opening or closing devices or equipment.

The apparatus of the present invention can be provided with or have a layer of insulation, which can protect the user from the electrical components of the apparatus as well as from the electrical circuit. The apparatus can also be equipped with or can have a shell and/or housing or casing, which may have any appropriate and/or ergonomic shape, which can further isolate the electrical components of the apparatus and which can protect the rest of the apparatus, or the components of same, from damage or destruction. The insulation and/or housing or casing can be shaped so as to allow the mechanical switch, dial, or switching device, to be accessible to the user, and can allow the output stimulus of the LED or any speaker to be detectable by the user. The housing of casing can be made or manufactured from plastic, hard rubber, or any other suitable material. The housing or casing can also provide further for additional insulation and protection.

### BRIEF DESCRIPTION OF THE DRAWINGS

In the Drawings:

FIG. 1 illustrates a schematic diagram of a preferred embodiment of the portable circuit-breaker tripper apparatus of the present invention; and

FIG. 2 illustrates a cross-sectional view of some of the major components of the preferred embodiment of the portable circuit-breaker tripper apparatus of FIG. 1 and illustrates additional components of another preferred embodiment of the apparatus of the present invention.

### DESCRIPTION OF THE PREFERRED EMBODIMENTS

The present invention pertains to a portable circuit-breaker tripper apparatus and method of using same and, in particular, the present invention pertains to a portable circuit-breaker tripper apparatus and method of using same which can be used to safely open or “trip” a circuit associated with a circuit breaker or an electrical fuse. The present invention provides an apparatus, and a method for using same, which is a useful tool for reliably and safely blowing a fuse or tripping a circuit breaker, while leaving other circuits unaffected.

Applicant hereby incorporates by reference herein the subject matter and teachings of U.S. Provisional Patent Application Ser. No. 62/106,101, filed Jan. 21, 2015, and entitled “PORTABLE CIRCUIT-BREAKER TRIPPER APPARATUS AND METHOD OF USING SAME”, the subject matter and teachings of which are hereby incorporated by reference herein in their entirety.

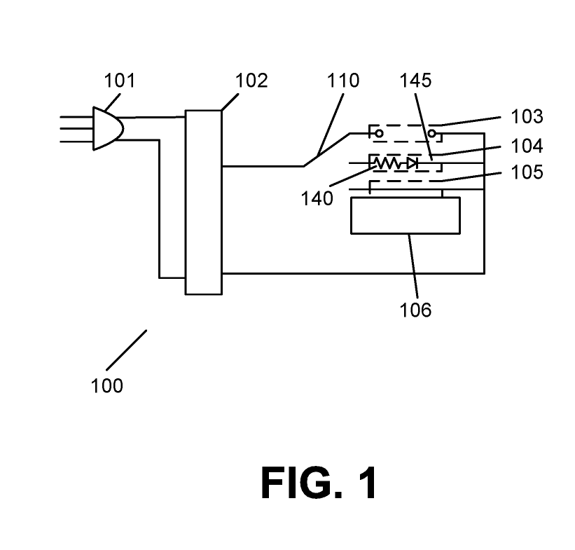

FIG. 1 illustrates a schematic diagram of a preferred embodiment of the portable circuit-breaker tripper apparatus of the present invention, which is denoted generally by the reference numeral 100. With reference to FIG. 1, in a preferred embodiment, the apparatus 100 of the present invention has an electrical plug 101 which allows the apparatus 100 of the present invention to interface with an external circuit 50, which can be a residential, a commercial, or any other electrical, outlet with an associated circuit breaker or fuse 55.

Connected electrically to the electrical plug 101 can be any appropriate electrical device or electrical load 102, or any electrical devices or electrical loads, such as, for example, but not limited to, an ammeter or a rectifying circuit, or any combination of same. In a preferred embodiment, the electrical load 102 can be connected to the electrical plug in a series or parallel connection with the electrical plug 101.

In yet another preferred embodiment of the present invention, the apparatus 100 can include a switching component 110 which can be connected in a series or parallel connection with either the electrical plug 101 and/or the electrical load 102.

In a preferred embodiment, the switching component 110 can be connected to an off load 103, a test load, 104, and/or trip load 105. The position of the switching component 110 can be used to electrically connect any of the off load 103, test load 104, and/or trip load 105, one at a time, with the electrical load 102 and/or the electrical plug 101.

In a preferred embodiment, the switching component 110 can be actuated by a mechanical dial 111, or any other appropriate mechanical switch, button, touch screen, or similar, device. In such a manner, a user of the apparatus 100 of the present invention can use the dial 111 to select which of the off load 103, the test load 104, or the trip load 105 is to be electrically connected to either the electrical plug 101 and/or the electrical load 102.

In yet another preferred embodiment of the present invention, the off load 103 can be an open circuit, or can be any other device or configuration, which would present a high and/or effectively infinite resistance between its terminals and to the external electrical circuit. In this regard, the off load 103 can be described as providing an open circuit in and for the apparatus 100 of the present invention.

In a preferred embodiment, effectively, no current, or a very minimal current, flows through the apparatus 100 and/or its circuitry when the switching component 110 is positioned such that the off load 103 is electrically connected with either the electrical plug 101 and/or the electrical load 102.

In a preferred embodiment, the test load 104 can consist of a resistive component 140 and/or a light emitting diode (LED) 145, or any combination of same. The resistive component 140 can be any device which serves to limit the amount of current, if available, which can flow through the LED 145. In a preferred embodiment, the LED 145 can be a light emitting diode, an organic light emitting diode, or the light emitting diode (LED) 145 can be replaced by or with, or can include, a buzzer, a speaker, and/or an alarm, and/or any other suitable device capable of indicating and/or producing a stimulus of light, sound, or any other suitable stimulus.

In a preferred embodiment, when the switching component 110 is positioned such that the test load 104 is electrically connected with either the electrical plug 101 and/or the electrical load 102, sufficient current can flow through the test load 104 such that the LED 145 produces a stimulus which can indicate, to the user of the apparatus 100 of the present invention, that the external circuit 50, which is connected to the apparatus 100, is providing power to the apparatus 100.

In yet another preferred embodiment of the present invention, the trip load 105 can be a circuit which presents minimal resistance or a “short” circuit, or any other device or configuration which would present a low and/or effectively zero or minimal resistance which would result in the tripping of the circuit breaker or the blowing of a fuse associated with the circuit, which is associated with the electrical outlet. In this regard, in a preferred embodiment, the trip load 105 is designed to trip the circuit breaker or blow the fuse associated with the circuit to which the apparatus 100 is connected.

In a preferred embodiment, high current flows through the apparatus 100 when the switching component 110 is positioned such that the trip load 105 is electrically connected with either the electrical plug 101 and/or the electrical load 102. Such a high current will result in the tripping of the circuit breaker, or the destroying or blowing of the fuse 55, of the external circuit 50 from the location where the apparatus 100 is being operated or utilized.

In yet another preferred embodiment, a heat sink 106 is thermally coupled to the trip load 105, such that the heat sink 106 can conduct and/or absorb any heat generated by any high current that can flow through the trip load 105 and ensure that the high current does not destroy the trip load 105, thereby allowing for the apparatus 100 of the present invention to be reusable. In a preferred embodiment, the heat sink 106 can be composed of any suitable material so that it can prevent any device or component to which it is thermally coupled from thermal damage, and especially thermal damage which might result due to, or as the result of, a high current flow. In a preferred embodiment, the heat sink 106 can also be coupled to any other component and/or device of the apparatus 100 of the present invention.

In a preferred embodiment, the dial 111 and/or the switching device 110 can include or be accompanied by suitable text to allow a user of the apparatus 100 of the present invention to be provided with a representation of which of the off load 103, test load 104, and/or trip load 105, is currently selected by, or can be selected by, the dial 111 and/or the switching device 110. As and for an example, the dial may read “OFF,” “TEST,” and “TRIP,” corresponding to electrical connections for each of the respective off load 103, test load 104 and/or trip load 105 positions and/or circuits.

In a preferred embodiment, the apparatus 100 of the present invention can be utilized in the following manner. With the dial 111 and/or the switching device 110 placed or located in the “OFF” position, the user can connect the electrical plug 101 with the outlet 51 of the external circuit 50, such as by simply plugging the electrical plug 101 into the electrical outlet 51. The user may then switch the position of, and/or the operation of, the dial 111 and/or the switching component 110 of the apparatus 100 to the “TEST” position, so as to determine, from the output, or lack thereof, of the LED 145 to determine if the external circuit 50 is respectively “live” or “dead”. If the user wishes to trip the circuit breaker or fuse 55 of the external circuit 50, without needing to be present at the location of the circuit breaker or fuse 55, the user can switch the dial 111 and/or the switching component 110 of the apparatus 100 to the “TRIP” position, effectively “shorting” the external circuit 50 and tripping and/or destroying the circuit breaker or fuse 55. The user may then switch the dial 111 and/or the switching component 110 of the apparatus 100 back to the “TEST” position to in order to verify the external circuit 50 has been disabled and is no longer a “live” circuit and, therefore, safe to work on.

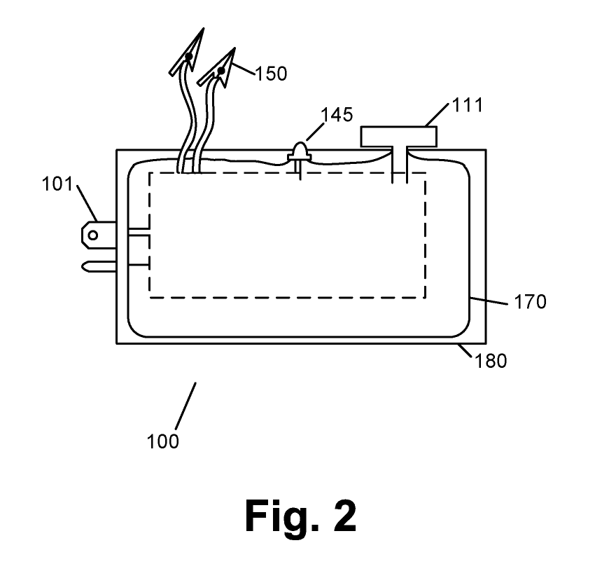

FIG. 2 illustrates a cross-sectional view of some of the major components of the preferred embodiment of the portable circuit-breaker tripper apparatus of FIG. 1 and illustrates additional components of another preferred embodiment of the apparatus of the present invention. With reference to FIG. 2, in a preferred embodiment, the apparatus 100 of the present invention includes a layer of insulation 170, located between the inner side of the shell, casing, or housing 180 (“housing 180”) and the electrical components of FIG. 1 of the apparatus 100. The insulation 170 protects the user from the electrical components of the apparatus 100. The apparatus 100, in the preferred embodiment, can be designed to have any appropriate and/or ergonomic shape. The housing 180, regardless of its shape and contour can also serve to further isolate the electrical components of the apparatus 100 and protect the rest of the apparatus 100 from damage. The insulation 170 and the housing 180, in a preferred embodiment, can be designed and shaped so as to allow the mechanical dial 111 to be accessible to the user and so that the output stimulus of the LED 145 can be detectable by the user. The housing 180 can be made of plastic, hard rubber, or any other suitable material, and/or any combination of same.

With reference to once again to FIG. 2, and in yet another preferred embodiment, the electrical load 102 of FIG. 1 can also be connected to a set of lead wires, alligator clips or other connective components 150, which can be used to connect the electrical load 102 to the circuit in place of the electrical plug 101. In such a manner, the apparatus 100 of the present invention can be interfaced with, and be utilized in conjunction with, circuits that do not have an associated wall outlet or electrical outlet, or for which an associated wall outlet is unknown to the user. As and for an example, connecting the lead wires of the electrical load 102 to the terminals of a light bulb socket would allow the operation of the apparatus 100 to “trip” the circuit breaker or “blow” the fuse, and, therefore, disable the circuit associated with the light bulb socket without the user needing to identify other components, such as a wall outlet or other outlet, that are or may be on the same electrical circuit as the light bulb socket. Similarly, the apparatus 100 can be used to disable a circuit associated with a dimmer switch.

While the present invention has been described and illustrated in various preferred and alternate embodiments, such descriptions are merely illustrative of the present invention and are not to be construed to be limitations thereof In this regard, the present invention encompasses all modifications, variations, and/or alternate, embodiments, with the scope of the present invention being limited only by the claims which follow.

What is claimed is:

1. An apparatus, comprising:
an electrical plug or a plurality of external electrical connectors;
a first circuit, wherein the first circuit is an open circuit or an essentially open circuit;
a second circuit, wherein the second circuit includes an indicator for indicating an electrical current flow in the second circuit;
a third circuit, wherein the third circuit is designed to open a fuse or to trip a circuit breaker; and
an electrical switch, wherein the electrical switch is electrically connected to the electrical plug or to the plurality of external electrical connectors, wherein the electrical switch is capable of connecting the electrical plug or the plurality of external electrical connectors to the first circuit, to the second circuit, or to the third circuit.

2. The apparatus of claim 1, further comprising:
a heat sink.

3. The apparatus of claim 2, wherein the third circuit is coupled to the heat sink.

4. The apparatus of claim 3, wherein the third circuit is thermally coupled to the heat sink.

5. The apparatus of claim 1, wherein the indicator is a light emitting diode, an organic light emitting diode, a buzzer, a speaker, or an alarm.

6. The apparatus of claim 1, further comprising:
a housing; and
an insulating material, wherein the housing houses the first circuit, the second circuit, and the third circuit, and the insulating material.

7. The apparatus of claim 1, further comprising:
a switch dial, wherein the switch dial is electrically connected to the electrical switch, and further wherein the switch dial is mounted on an exterior of the housing.

8. The apparatus of claim 1, wherein the plurality of external electrical connectors contains at least one alligator clip.

9. A method for opening a circuit protected by a circuit breaker with a portable circuit-breaker tripping apparatus, comprising:
setting a switch on the portable circuit-breaker tripper apparatus to a first position corresponding to an open circuit;
plugging the portable circuit-breaker tripper apparatus into an electrical outlet;
setting the switch to a second position for testing whether the electrical outlet is providing electrical power; and
setting the switch to a third position, wherein the third position causes a circuit breaker associated with a circuit associated with the electrical outlet to open or trip.

10. A method for opening a circuit protected by a circuit breaker with a portable circuit-breaker tripping apparatus, comprising:
setting a switch on the portable circuit-breaker tripper apparatus to a first position corresponding to an open circuit;
attaching an electrical connector or electrical connectors across an electrical circuit;
setting the switch to a second position for testing whether the electrical circuit is providing electrical power; and
setting the switch to a third position, wherein the third position causes a circuit breaker associated with the electrical circuit to open or trip.
